(19) United States
(12) Patent Application Publication
(10) Pub. No.: US 2008/0003799 A1
(43) Pub. Date: Jan. 3, 2008

(54) Method for forming contact plug in semiconductor device

(75) Inventors: Young-Jun Kim, Kyoungki-do (KR); Kyoung-Sik Han, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,872

(22) Filed: Dec. 28, 2006

(30) Foreign Application Priority Data
Jun. 29, 2006 (KR) 2006-0059599

(51) Int. Cl. H01L 21/44

(52) U.S. Cl. 438/597

(57) ABSTRACT

A method for forming a contact plug in a semiconductor device includes providing a substrate where an isolation structure is formed, forming an insulation layer over the substrate, wherein the insulation layer has a contact hole exposing an active region between the isolation structure and the insulation layer performing a cleaning process by adjusting a selectivity between the isolation structure and the insulation layer to remove residues of the insulation layer existing over a bottom portion of the contact hole without a loss of the isolation structure, and forming a contact plug isolated in the contact hole.

### CROSS-REFERENCE TO RELATED APPLICATIONS

The present invention claims priority of Korean patent application number 10-2006-0059599, filed on Jun. 29, 2006, which is incorporated by reference in its entirety.

### BACKGROUND OF THE INVENTION

The present invention relates to a fabrication technology of a semiconductor device, and more particularly, to a method for forming a contact plug, e.g., source and drain contact plugs, in a NAND flash memory device.

Data stored in a cell of a nonvolatile memory device such as a flash memory device are not lost even if power supply is interrupted. Thus, the flash memory device is being widely used for a memory card, etc. The flash memory device is mainly classified into two types, of which one is a NAND flash memory device and the other is a NOR flash memory device.

A memory cell array of the NAND flash memory device is configured with a plurality of strings. Here, each of the strings includes a string select transistor, a plurality of cell transistors, and a ground select transistor, which are connected in series. A drain region of the string select transistor is connected to a bit line through a drain contact plug, and a source region of the ground select transistor is connected to a common source line through a source contact plug.

Meanwhile, with a high integration of the NAND flash memory device currently, space margins between the drain contact plugs and between the source contact plugs are gradually decreased but an aspect ratio for device isolation is increased. Furthermore, as the NAND flash memory device is highly integrated, there occurs a void or a seam in an isolation structure when forming the isolation structure using a typical high density plasma (HDP) oxide layer. Therefore, in recent years, there has been proposed a technology of using a spin on dielectric (SOD) layer with sufficient fluidity when forming the isolation structure having a high aspect ratio.

The SOD layer, however, has a much higher wet etch rate than the HDP layer. Therefore, when performing a cleaning process to remove residues of the HDP layer before forming the source or drain contact plug, the loss amount is largely increased. This causes the source and drain contact plugs to be directly in contact with the substrate at a portion where the SOD layer is removed.

FIG. 1 illustrates a scanning electron microscope (SEM) micrograph showing a limitation of a typical method for forming a source contact plug in a NAND flash memory device caused by a loss of an isolation structure. For example, the SOD layer with a high wet etch rate is almost removed during the cleaning process performed before forming the source contact plug. Thus, the source contact plug may come directly in contact with the substrate Si-SUB exposed by the loss of the SOD layer (see ‘A’ in FIG. 1).

FIGS. 2(A) and 2(B) illustrate SEM micrographs showing a limitation of a typical method for forming a drain contact plug in a NAND flash memory device due to a loss of an isolation structure. One side of the SOD layer with a high wet etch rate is almost removed during the cleaning process performed before forming the drain contact plug. Thus, one side of the drain contact plug may come directly in contact with the substrate Si-SUB (see ‘A’ in FIGS. 2(A) and 2(B)). Accordingly, when the source and drain contact plugs are in contact with the substrate, a leakage current may be generated along a contact portion thereof.

### SUMMARY OF THE INVENTION

Embodiments of the present invention are directed to provide a method for forming a contact plug in a semiconductor device, which can cut off a leakage current by minimizing a loss of an isolation structure during cleaning processes performed before forming a contact plug of a flash memory device, e.g., source and drain contact plugs, respectively.

In accordance with an aspect of the present invention, there is provided a method for forming a contact plug in a semiconductor device, the method including: providing a substrate where an isolation structure is formed; forming an insulation layer over the substrate, wherein the insulation layer has a contact hole exposing an active region between the isolation structure and the insulation layer; performing a cleaning process by adjusting a selectivity between the isolation structure and the insulation layer to remove residues of the insulation layer existing over a bottom portion of the contact hole without a loss of the isolation structure; and forming a contact plug isolated in the contact hole.

In accordance with another aspect of the present invention, there is provided a method for forming a contact plug in a semiconductor device, the method including: forming a plurality of gate electrodes over a substrate where an isolation structure is formed; forming a plurality of source and drain regions in the substrate exposed between the gate electrodes; forming an etch stop layer over the resultant substrate structure including the gate electrodes; forming a first insulation layer over the etch stop layer and filled between the gate electrodes; etching the first insulation layer and the etch stop layer to form a first contact hole exposing at least one source region; performing a first cleaning process by adjusting an etch selectivity between the isolation structure and the first insulation layer to remove residues of the first insulation layer existing over a bottom portion of the first contact hole without a loss of the isolation structure; and forming a source contact plug isolated in the first contact hole.

### BRIEF DESCRIPTION OF THE DRAWINGS

FIG. 1 illustrates a scanning electron microscope (SEM) micrograph showing a limitation of a typical method for forming a source contact plug in a NAND flash memory device caused by a loss of an isolation structure.

FIGS. 2(A) and 2(B) illustrate SEM micrographs showing a limitation of a typical method for forming a drain contact plug in a NAND flash memory device caused by a loss of an isolation structure.

FIGS. 3 to 7 illustrate cross-sectional views of a method for forming source and drain contact plugs in a NAND flash memory device in accordance with an embodiment of the present invention.

FIG. 8 is a SEM micrograph showing a sectional view of a source contact plug of a NAND flash memory device in accordance with the embodiment of the present invention.

FIG. 9 is a SEM micrograph showing a sectional view of a drain contact plug of a NAND flash memory device in accordance with the embodiment of the present invention.

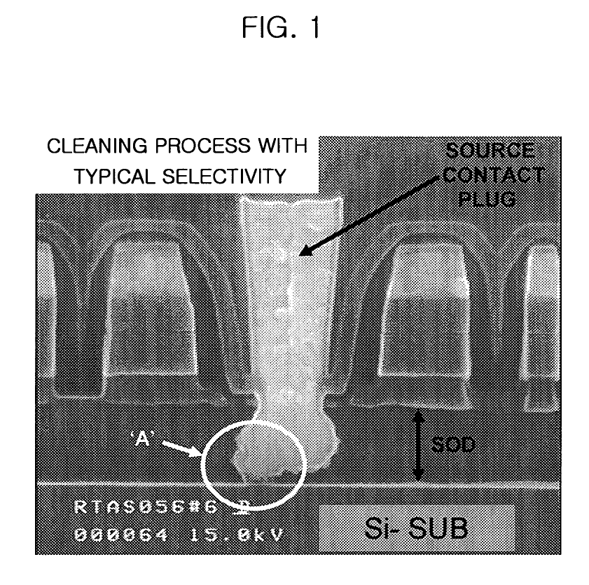

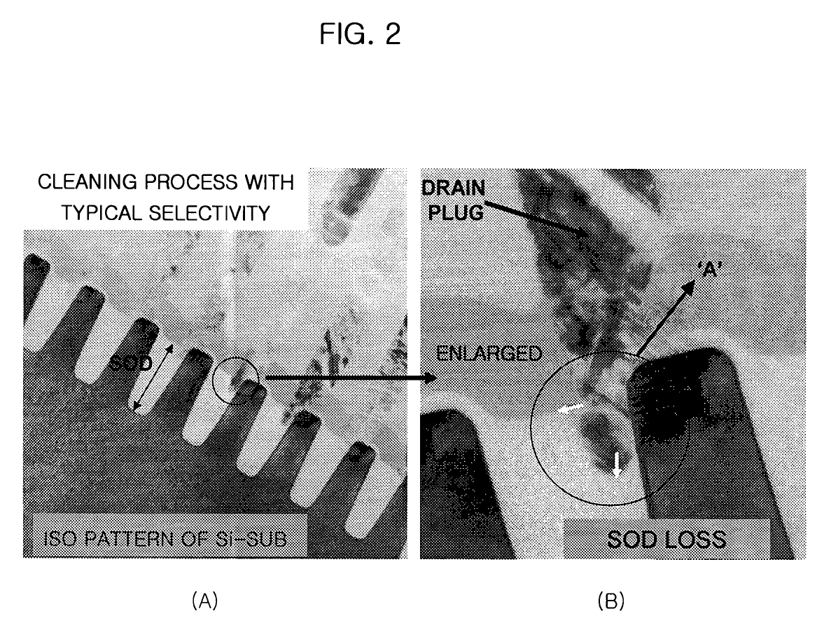

### DESCRIPTION OF SPECIFIC EMBODIMENTS

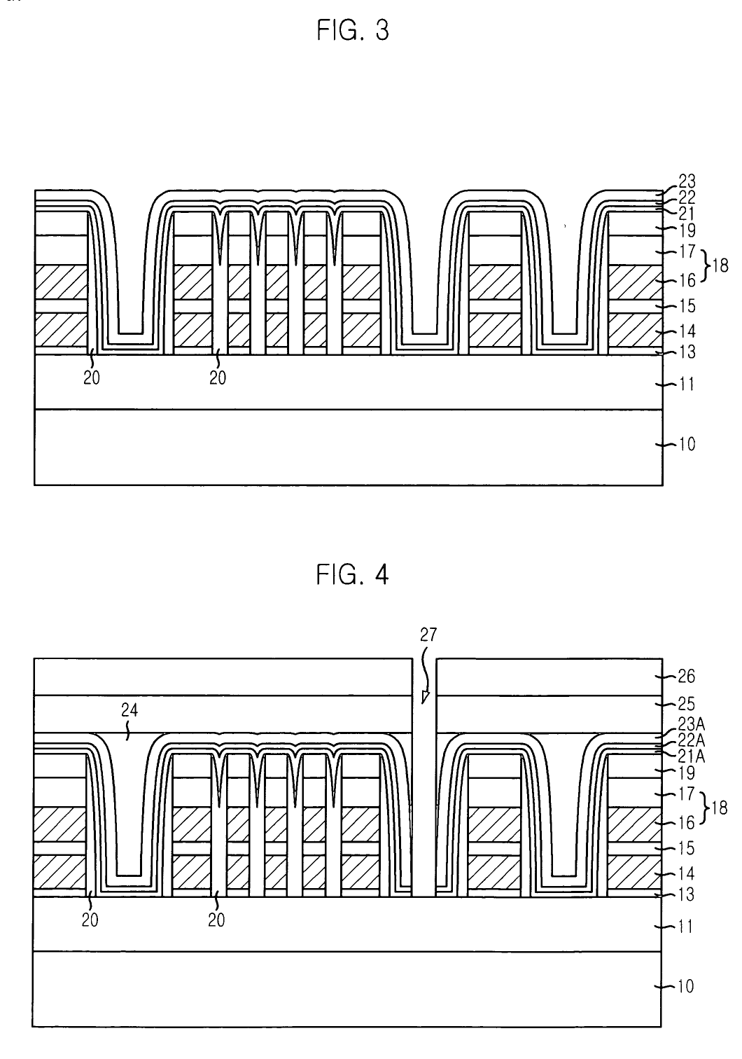

FIGS. 3 to 7 illustrate cross-sectional views of a method for forming source and drain contact plugs in a NAND flash memory device in accordance with an embodiment of the present invention. For convenience in description, an active region and a field region are shown together in FIGS. 3 to 7 along a bit line direction.

Referring to FIG. 3, an isolation structure 11 is formed in a substrate 10 through an isolation process. The isolation structure 11 is formed of a spin on dielectric (SOD) layer with satisfactory fluidity. Thus, the isolation structure 11 is sufficiently filled in a trench having a high aspect ratio. A tunnel insulating layer 13, a floating gate 14, a dielectric layer 15, a control gate 18 and a hard mask nitride layer 19 are sequentially formed over the substrate 10 thereby forming a cell with a stacked gate structure. Herein, the control gate 18 is configured with a polysilicon layer 16 and a tungsten silicide layer 17 formed thereon for improving a resistance.

An ion implantation process is performed to form a source (not shown) and a drain (not shown) in an active region of the substrate 10. A thermal oxidation process is performed to form spacers 20 on sidewalls of the stacked gate structure. A first buffer oxide layer 21 and a second buffer oxide layer 22 are formed in sequence along a profile of the stacked gate structure with the spacers 20 formed. An etch stop layer 23 is deposited on the second buffer oxide layer 22. For instance, the etch stop layer 23 may include a nitride-based material.

Referring to FIG. 4, a first insulation material layer is formed over the etch stop layer 23 for insulating the stacked gate structures from each other. The first insulation material layer is formed of an oxide-based material such as borophosphosilicate glass (BPSG), high density plasma (HDP) oxide, low pressure-tetraethyl orthosilicate (LP-TEOS), plasma enhanced-TEOS (PE-TEOS), or the like. For instance, the first insulation material layer may be formed of the HDP oxide having sufficient gap-fill property. The first insulation material layer is planarized using a chemical mechanical polishing (CMP) until a top surface of the etch stop layer 23 is exposed. Thus, an upper surface of the resultant structure is planarized. A second insulation material layer is deposited on the resultant structure including the first insulation material layer. The second insulation material layer is formed of substantially the same oxide-based material as the first insulation material layer. The second insulation material layer may be formed of the HDP oxide.

A photoresist pattern 26 is formed on the second insulation material layer. The photoresist pattern 26, which is a source contact mask for defining a source contact region where a source contact plug will be formed, is formed in such a structure that the photoresist pattern 26 exposes the source contact region. The second and first insulation material layers are etched using the photoresist pattern 26 as a mask to form a source contact hole 27, a first insulation layer 24, and a second insulation layer 25. The source contact hole 27 exposes the isolation structure 11 of the source contact region. Although not shown, the source contact hole 27 also exposes a surface of the substrate 10 of the active region where the source of the flash memory device is formed. Reference denotations 21A, 22A, and 23A represent a patterned first buffer oxide layer, a patterned second buffer oxide layer, and a patterned etch stop layer, respectively.

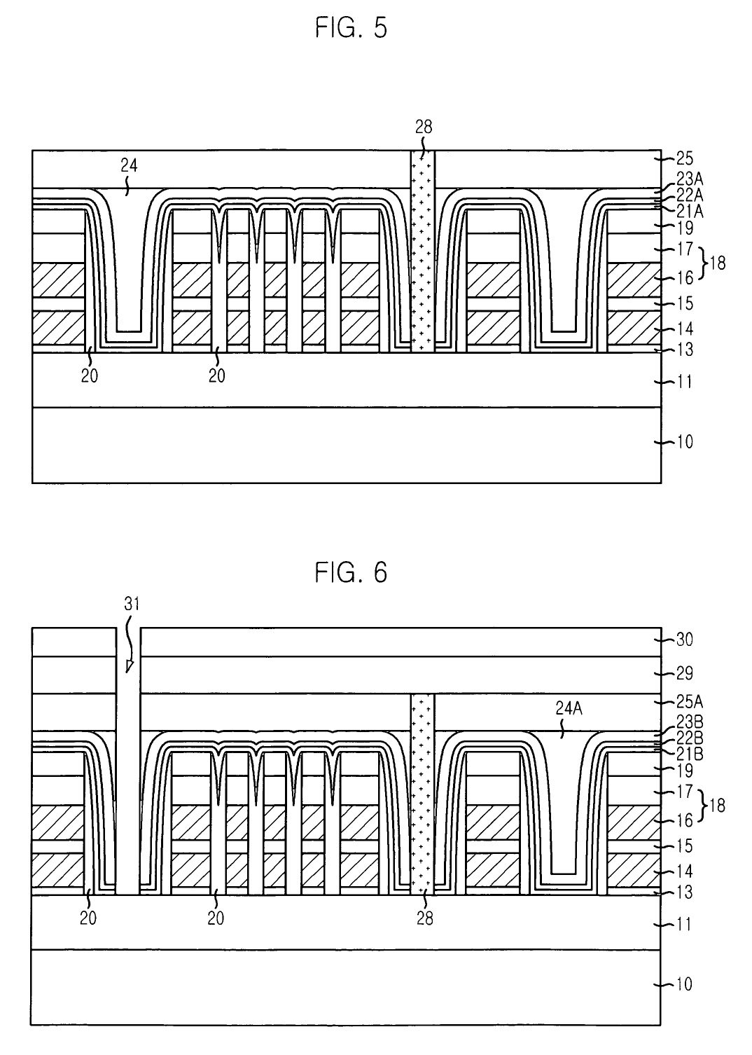

Referring to FIG. 5, a removal process is performed to remove the photoresist pattern 26 and a cleaning process is performed to remove remaining impurities. Here, the cleaning process is performed using a certain chemical having little etch selectivity between the HDP oxide layer constituting the first and second insulation layers 24 and 25, and the SOD layer constituting the isolation structure 11.

For reference, the cleaning process is typically performed using a buffered oxide etchant (BOE) solution in which hydrogen fluoride (HF) and ammonium fluoride (NH₄F) are mixed at a ratio of approximately 300:1, or a diluted HF (DHF) solution in which HF is diluted with water at a ratio of approximately 100:1. However, if using this BOE or DHF solution, an etch rate of the SOD layer is higher than that of the insulation layer so that the SOD layer is easily and rapidly etched. That is, if using the typical method, the SOD layer is substantially etched to a large amount in comparison with the insulation layer.

Accordingly, the present invention employs a certain chemical having little etch selectivity between the insulation layer and the SOD layer. This is to prevent the SOD layer from being easily etched with impurities of the HDP oxide layer. Therefore, it is possible to prevent the loss of the SOD layer during the cleaning process performed before forming the source contact plug 28.

In particular, the chemical used in the cleaning process is a chemical having an etch selectivity between the SOD layer and the first and second insulation layers 24 and 25 ranging approximately 1:0.3-1.7. That is, the etch selectivity between the SOD layer and the first and second insulation layers 24 and 25 is varied with a material constituting the first and second insulation layers 24 and 25. For example, when the first and second insulation layers 24 and 25 are formed of BPSG, the etch selectivity between the SOD layer and the first and second insulation layers 24 and 25 is set at approximately 1:1.7. When the first and second insulation layers 24 and 25 are formed of HDP oxide, the etch selectivity between the SOD layer and the first and second insulation layers 24 and 25 is set at approximately 1:0.3. When the first and second insulation layers 24 and 25 are formed of LP-TEOS, the etch selectivity between the SOD layer and the first and second insulation layers 24 and 25 is set at approximately 1:1.4. When the first and second insulation layers 24 and 25 are formed of PE-TEOS, the etch selectivity between the SOD layer and the first and second insulation layers 24 and 25 is set at approximately 1:0.6.

The chemical having the above etch selectivity includes a chemical in which an organic compound, HF and an amine composition are mixed. Herein, the organic compound includes a kind of glycol, e.g., tripropyleneglycol menomethyl ether, and the amine composition includes monoethylamine. The chemical is composed of approximately 99% of the organic compound, approximately 0.08% of the HF and approximately 0.09% of the amine composition and deionized water as the rest.

That is, when using this mixed chemical, the etch selectivity between the insulation layer and the SOD layer is decreased in comparison with the typical method so that there is little etch selectivity therebetween. For instance, the SOD layer is rapidly etched because the etch selectivity between the insulation layer and the SOD layer ranges from approximately 1:4.6-5.8 when using the typical BOE and DHF solution. Whereas, when employing the mixed chemical in accordance with the present invention, the etch selectivity between the insulation layer and the SOD layer ranges from approximately 1:0.3-1.7 so that the SOD layer is rarely etched. Accordingly, it is possible to minimize the loss of the SOD layer. In particular, this cleaning process is performed for approximately 70 seconds to approximately 90 seconds. For instance, the cleaning process may be performed for approximately 80 seconds.

A source contact plug 28 is formed in the source contact hole 27. Specifically, the source contact plug 28 is formed by depositing a polysilicon layer on the resultant structure to fill the source contact hole 27. The polysilicon layer is planarised using a CMP process or an etch-back process.

Referring to FIG. 6, a third insulation material layer is formed on the resultant structure where the source contact plug 28 is formed. The third insulation material layer is formed of substantially the same material as the second insulation layer 25. For instance, the third insulation material layer may be formed of HDP oxide. A bottom anti-reflective coating layer (BARC, not shown) is formed over the third insulation material layer, and a photoresist pattern 30 is then formed. Herein, the photoresist pattern 30, which is a drain contact mask for defining a drain contact region where a drain contact plug will be formed, is formed in such a shape that the photoresist pattern 30 exposes the drain contact region.

The third insulation material layer and the second and first insulation layers 25 and 24 are etched using the photoresist pattern 30 as a mask, thereby forming a drain contact hole 31, a third insulation layer 29, a patterned second insulation layer 25A, and a patterned first insulation layer 24A. The drain contact hole 31 exposes the isolation structure 11 of the drain contact region. Although not shown, the drain contact hole 31 exposes a surface of the substrate 10 of the active region where the drain of the flash memory device is formed. Reference denotations 21B, 22B, and 23B represent a further patterned first buffer oxide layer, a further patterned second buffer oxide layer, and a further patterned etch stop layer, respectively.

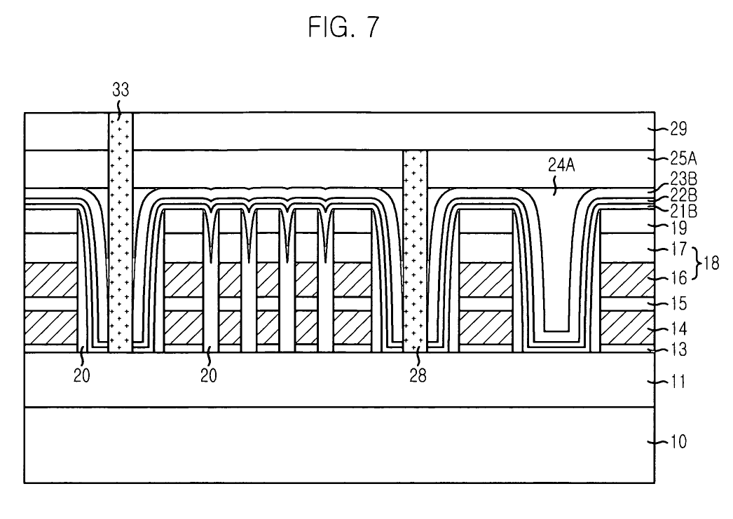

Referring to FIG. 7, a removal process is performed to remove the photoresist pattern 30 and the BARC layer (not shown). A cleaning process is performed to remove remaining impurities of the HDP oxide. In particular, the cleaning process is performed using a certain chemical having little etch selectivity between the HDP oxide layer constituting the first, second and third insulation layers 24, 25 and 29, and the SOD layer constituting the isolation structure 11. i.e., using substantially the same chemical used in the cleaning process performed after forming the source contact hole 27. The chemical includes a chemical having an etch selectivity between the SOD layer and the insulation layer of approximately 1:0.3-1.7. This is to prevent the SOD layer from being easily etched and removed together with residues of the HDP oxide layer during the cleaning process. Thus, in accordance with the present invention, it is possible to minimize the loss of the SOD layer during the cleaning process performed before forming a drain contact plug 33. In particular, the cleaning process is performed for approximately 30 seconds to approximately 50 seconds. For instance, the cleaning process may be performed for approximately 40 seconds.

A conductive layer (not shown) for a drain contact is deposited such that the conductive layer fills the drain contact hole 31. Here, the conductive layer for the drain contact may be formed using a polysilicon layer. In addition to the polysilicon layer, the conductive layer may be formed of tungsten, copper, aluminum, etc. A planarization process is performed using CMP or etch-back process to planarize the conductive layer for the drain contact. The planarization process is performed on condition that an etch selectivity between the third insulation layer 29 and the conductive layer for the contact plug, i.e., the polysilicon layer, is approximately 1:1. Thus, a drain contact plug 33 is formed, which fills the drain contact hole 31.

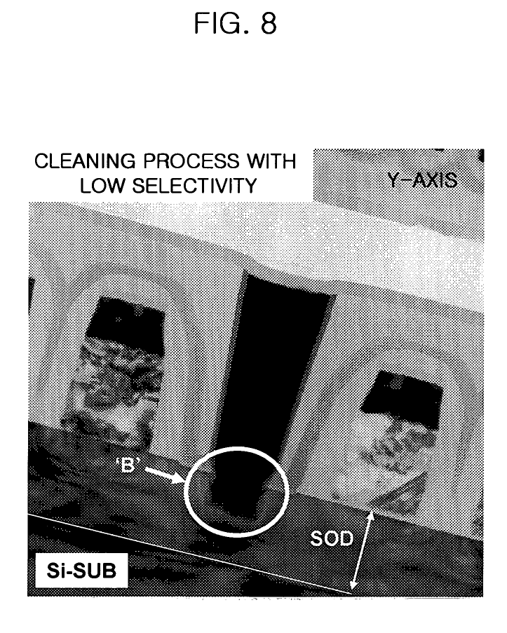

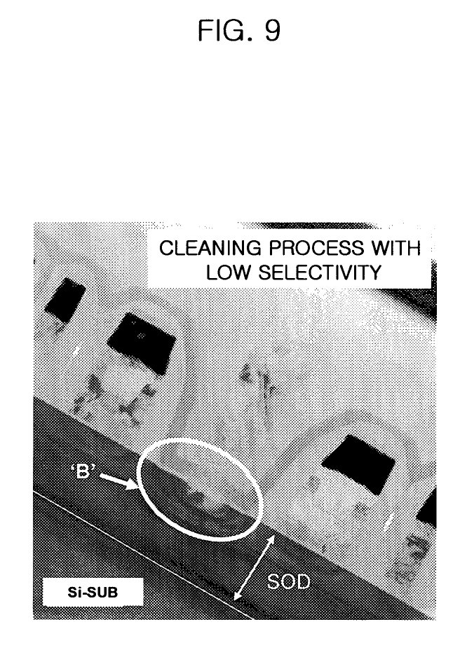

FIGS. 8 and 9 are SEM micrographs showing sectional views of source and drain contact plugs 28 and 33 of a NAND flash memory device in accordance with the embodiment of the present invention, respectively. Referring to FIG. 8, it is understood that the source contact plug 28 is formed without a loss of the SOD layer (see ‘B’ in FIG. 8) when performing the cleaning process using a low selectivity chemical before forming the source contact plug 28. Likewise, referring to FIG. 9, it is understood that the drain contact plug 33 is formed without a loss of the SOD layer (see ‘B’ in FIG. 9) when performing the cleaning process using a low selectivity chemical before forming the drain contact plug 33.

As described above, in accordance with the present invention, the chemical having the etch selectivity between the SOD layer and the insulation layer of approximately 1:0.3-1.7 is used during the cleaning process which is performed before forming each of the source and drain contact plugs. Accordingly, the loss of the SOD layer is suppressed so that it may become possible to cut off the leakage current.

While the present invention has been described with respect to the specific embodiments, it will be apparent to those skilled in the art that various changes and modifications may be made without departing from the spirit and scope of the invention as defined in the following claims.

What is claimed is:

1. A method for forming a contact plug in a semiconductor device, the method comprising:
providing a substrate where an isolation structure is formed;
forming an insulation layer over the substrate, wherein the insulation layer has a contact hole exposing an active region between the isolation structure and the insulation layer;
performing a cleaning process by adjusting a selectivity between the isolation structure and the insulation layer to remove residues of the insulation layer existing over a bottom portion of the contact hole without a loss of the isolation structure; and
forming a contact plug isolated in the contact hole.

2. The method of claim 1, wherein the cleaning process is performed using a chemical having an etch selectivity between the isolation structure and the insulation layer of approximately 1:0.3-1.7.

3. The method of claim 1, wherein the isolation structure includes a spin on dielectric (SOD) layer, and the insulation layer includes an oxide-based layer.

4. The method of claim 1, wherein when the insulation layer includes a borophosphosilicate glass (BPSG) layer and the isolation structure includes a SOD layer, the cleaning process is performed using a chemical having an etch selectivity between the BPSG layer and the SOD layer of approximately 1:1.7.

5. The method of claim 1, wherein when the insulation layer includes a high density plasma (HDP) layer and the isolation structure includes an SOD layer, the cleaning process is performed using a chemical having an etch selectivity between the HDP layer and the SOD layer of approximately 1:0.3.

6. The method of claim 1, wherein when the insulation layer includes a low pressure-tetraethyl orthosilicate (LP-TEOS) layer and the isolation structure includes an SOD layer, the cleaning process is performed using a chemical having an etch selectivity between the LP-TEOS layer and the SOD layer of approximately 1:1.4.

7. The method of claim 1, wherein when the insulation layer includes a plasma enhanced-TEOS (PE-TEOS) layer and the isolation structure includes an SOD layer, the cleaning process is performed using a chemical having an etch selectivity between the PE-TEOS layer and the SOD layer of approximately 1:0.6.

8. The method of claim 1, wherein the cleaning process is performed using a chemical including an organic compound, hydrogen fluoride (HF), an amine composition, and deionized water.

9. The method of claim 8, wherein the chemical includes approximately 99% of the organic compound, approximately 0.08% of the HF, approximately 0.09% of the amine composition and the deionized water as the rest.

10. A method for forming a contact plug in a semiconductor device, the method comprising:
forming a plurality of gate electrodes over a substrate where an isolation structure is formed;
forming a plurality of source and drain regions in the substrate exposed between the gate electrodes;
forming an etch stop layer over the resultant substrate structure including the gate electrodes;
forming a first insulation layer over the etch stop layer and filled between the gate electrodes;
etching the first insulation layer and the etch stop layer to form a first contact hole exposing at least one source region;
performing a first cleaning process by adjusting an etch selectivity between the isolation structure and the first insulation layer to remove residues of the first insulation layer existing over a bottom portion of the first contact hole without a loss of the isolation structure; and
forming a source contact plug isolated in the first contact hole.

11. The method of claim 10, further comprising:
forming a second insulation layer over the resultant substrate structure including the source contact plug;
etching the second insulation layer, the first insulation layer and the etch stop layer to form a second contact hole exposing at least one drain region;
performing a second cleaning process by adjusting an etch selectivity between the isolation structure and the first and second insulation layers to remove residues of the first and second insulation layers existing over a bottom portion of the second contact hole without a loss of the isolation structure; and
forming a drain contact plug isolated in the second contact hole.

12. The method of claim 11, wherein the first and second cleaning processes are performed using a chemical having an etch selectivity between the isolation structure and the first and second insulation layers of approximately 1:0.3-1.7.

13. The method of claim 11, wherein the isolation structure includes an SOD layer, and the first and second insulation layers include an oxide-based layer.

14. The method of claim 11, wherein when the first and second insulation layers include a BPSG layer and the isolation structure includes an SOD layer, the first and second cleaning processes are performed using a chemical having an etch selectivity between the BPSG layer and the SOD layer of approximately 1:1.7.

15. The method of claim 11, wherein when the first and second insulation layers include an HDP layer and the isolation structure includes an SOD layer, the first and second cleaning processes are performed using a chemical having an etch selectivity between the HDP layer and the SOD layer of approximately 1:0.3.

16. The method of claim 11, wherein when the first and second insulation layers include an LP-TEOS layer and the isolation structure includes an SOD layer, the first and second cleaning processes are performed using a chemical having an etch selectivity between the LP-TEOS layer and the SOD layer of approximately 1:1.4.

17. The method of claim 11, wherein when the first and second insulation layers include a PE-TEOS layer and the isolation structure includes an SOD layer, the first and second cleaning processes are performed using a chemical having an etch selectivity between the PE-TEOS layer and the SOD layer of approximately 1:0.6.

18. The method of claim 11, wherein the first and second cleaning processes are performed using a chemical including an organic compound, HF, an amine composition, and deionized water.

19. The method of claim 18, wherein the chemical includes approximately 99% of the organic compound, approximately 0.08% of the HF, approximately 0.09% of the amine compound and the deionized water as the rest.
